(19) United States
(12) Patent Application Publication
(10) Pub. No.: US 2010/0258529 A1
(43) Pub. Date: Oct. 14, 2010

(54) Plasma Processing Apparatus and Plasma Processing Method

(76) Inventors: Masahito MORI, Tokorozawa-shi (JP); Tsutomu Tetsuka, Tokyo (JP); Naoshi Itabashi, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/496,689

(22) Filed: Jul. 2, 2009

(30) Foreign Application Priority Data
Jul. 2, 2008 (JP) 2008-173762

(51) Int. Cl. H01L 21/306; H01L 21/02; C23C 16/513

(52) U.S. Cl. 216/67; 156/345.28; 156/345.24; 118/712; 427/569

(57) ABSTRACT

The invention provides a plasma processing apparatus comprising a means for detecting the apparatus condition related to the ion flux quantity of plasma (plasma density) and the distribution thereof for to stabilizing mass production and minimizing apparatus differences. The plasma processing apparatus comprises a vacuum reactor 108, a gas supply means 111, a pressure control means, a plasma source power supply 101, a lower electrode 113 on which an object to be processes 112 is placed within the vacuum reactor, and a high frequency bias power supply 117, further comprising a probe high frequency oscillation means 103 for supplying an oscillation frequency that differs from the plasma source power supply 101 and the high frequency bias power supply 117 into the plasma processing chamber, high frequency receivers 114 through 116 for receiving the high frequency supplied from the probe high frequency oscillation means 603 via a surface coming into contact with plasma, and a high frequency analysis means 110 for measuring the impedance per oscillation frequency within an electric circuit formed by the probe high frequency oscillation means 603 and the receivers 114 through 116, the reflectance and the transmittance, and the variation of harmonic components.

The present application is based on and claims priority of Japanese patent application No. 2008-173762 filed on Jul. 2, 2008, the entire contents of which are hereby incorporated by reference.

### BACKGROUND OF THE INVENTION

1. Field of the Invention

The present invention relates to a plasma processing apparatus and a plasma processing method used for performing dry etching and CVD in the process for manufacturing semiconductor devices and flat panel displays (FPD).

2. Description of the Related Art

Etching devices are required to have a high operating rate and a high yield in a dry etching step, which is one of the steps for manufacturing semiconductor devices and FPD. In order to improve the operating rate, clustering of the apparatus is promoted in which a single apparatus is equipped with a plurality of chambers, and in that case, the differences in performances among chambers (inter-chamber difference) or among apparatuses (inter-apparatus difference) must be minimized.

On the other hand, in order to realize high yield, it is necessary to improve the in-plane uniformity of the object to be processed and the mass production stability. In order to realize in-plane uniformity and mass-production stability, based on etching principles, it is necessary that the incident flux of neutral radicals and ions and the ion incidence energy are made uniform within the plane of the object to be processed, and that the changes thereof accompanying the passing of processing time are suppressed.

One of the viewpoints for realizing mass production stability is to prevent particle generation and to prevent contamination, and an art is disclosed (refer for example to Japanese patent application laid-open publication No. 2007-250755, hereinafter referred to as patent document 1) which the plasma impedance is monitored via a DC power supply applied to an electrostatic chuck means or via a bias application means or a plasma generating means, thereby predicting abnormality of the apparatus such as generation of particles, based on which parts are replaced and maintenance is performed.

Moreover, from the viewpoint of uniformizing and stabilizing the flux ratio of neutral radicals and ions, an advanced process control (APC) technique exists in which the quantities of neutral radicals and ions are detected in some way to perform feedback control of the apparatus parameters. For example, plasma emission spectroscopy is a general method for detecting the relative quantitative variation of neutral radicals. At this time, by disposing a plurality of receivers for receiving the plasma emission along the in-plane direction, the variation of in-plane distribution of neutral radicals emitting light can be detected so as to correct the plasma distribution.

On the other hand, Langmuir probe measurement is a general method for detecting the ion flux, but the introduction of the probe itself causes particle generation, contamination and disturbance of processing plasma, so that it is difficult to apply the method to mass production apparatuses. Recently, a method for measuring the plasma density in a non-contaminating and simple manner has been proposed, which adopts a structure where a high frequency antenna is covered with an insulating pipe (refer for example to Japanese patent application laid-open publication No. 2005-203124, hereinafter referred to as patent document 2). Further, a method is proposed for acquiring information including plasma density by monitoring the voltage current of an existing power supply from a wall surface (refer for example to Japanese patent application laid-open publication No. 08-222396, hereinafter referred to as patent document 3).

### SUMMARY OF THE INVENTION

In the etching process, the main cause that variesetching performance is the changes of condition with time of the inner wall surface of the chamber. When the wall surface condition is varied due to deposits and surface alteration, the composition ratio of particles desorbed from the wall surface and the amount thereof are varied, so that the composition of neutral radicals in the plasma is also varied. Further, since the amount of secondary electron emission from the wall surface is also varied, the in-plane distribution of plasma density changes from the area close to the wall surface, and the density of the whole plasma is also varied. However, through conventional monitoring (such as the plasma emission, the RF bias Vₚₚ of the apparatus control parameter or the matching point of source power), it was difficult to distinguish whether the variation appearing on the monitor was caused by the changes of plasma density or by the changes of neutral radicals. Furthermore, the consumption of the components in the apparatus and the degradation of the insulation coating also causes the plasma density and the neutral radical composition to vary, but since the level of consumption of components and the replacement timings thereof were conventionally determined based on the prescribed discharge time, when the level of consumption of a component exceeded the predicted level, particles were generated and failure occurred, by which the yield was deteriorated.

The plasma density measurement adopting the high frequency antenna probe method disclosed in patent document 2 is advantageous regarding metal contamination and stability, but considering the principle that the surface waves existing between the high frequency antenna and the dielectric body resonate with the plasma close to the probe, the method is only capable of obtaining the plasma density close to the probe and not the data regarding the density within the plasma. The methods disclosed in patent document 1 and patent document 3 also detect the level of consumption of the components of the apparatus and the changes of plasma density in a mixture, so that the methods could not distinguish the respective changes.

The object of the present invention is to provide a plasma processing apparatus capable of detecting the conditions of the apparatus such as the density and distribution of plasma and the consumption of components, which are physical parameters of controlling the plasma processing performance. In addition, the present invention aims at providing a plasma processing method capable of realizing the improvement of stability of the plasma processing performance and the APC for directly controlling the physical parameters, realizing preventive maintenance of the components and the apparatus, and realizing failure diagnosis.

The present invention aims at solving the problems of the prior art by providing a plasma processing apparatus comprising a vacuum reactor, a gas supplying means for introducing plasma-forming gas into the vacuum reactor, a pressure control means for controlling the pressure of said gas introduced into the vacuum reactor, a plasma generating means for generating plasma using the gas introduced into the vacuum reactor, a placing means for placing an object to be subject to plasma processing in the vacuum reactor, and a high frequency bias applying means for applying high frequency bias to the placing means, wherein the apparatus further comprises a probe high frequency oscillation means for supplying into the vacuum reactor (plasma processing chamber) a minute output oscillation frequency that differs from a plasma source power supply of the plasma generation means and from a high frequency bias power supply of the high frequency bias applying means, a plurality of high frequency receiver means disposed along a parallel direction and a perpendicular direction with respect to the surface of the object to be processed for receiving the high frequency supplied from the probe high frequency oscillation means via a plane that contacts the plasma via an insulating layer, and a high frequency analysis means for measuring the impedance per oscillation frequency or for measuring a reflectance and a transmittance per oscillation frequency within an electric circuit formed of the probe high frequency oscillation means and the high frequency receiver means, and computing a variation of the plasma density and distribution of the plasma using the measured impedance or the measured reflectance and transmittance.

Further, the present object can be realized by arranging the plurality of high frequency receiver means along a radial direction and a perpendicular direction with respect to the surface of the object to be processed in the plasma processing apparatus. Moreover, the present object can be realized by the above-mentioned plasma processing apparatus, in which the probe high frequency oscillation means has a frequency sweeping means, the sweep frequency supplied from the frequency sweeping means contains a plasma frequency corresponding to the plasma density, and the high frequency receiver means synchronizes with the sweeping frequency. Further, the probe high frequency oscillation means is equipped with a frequency sweeping means, and the supplied sweeping frequency includes the plasma frequency corresponding to the plasma density (100 kHz or greater and 3 GHz or smaller), and even further, the high frequency receiver means is synchronized with the sweeping frequency, and the high frequency receiver means is disposed on the plasma processing chamber side wall and on the side of the means for placing the object to be processed.

The above-mentioned object is realized by the above-mentioned plasma processing apparatus in which the high frequency receiver means are disposed on the plasma processing chamber side wall within the vacuum reactor and on the side of the means for placing the object to be processed, the high frequency receiver means disposed in the perpendicular direction with respect to the surface of the plasma is an electrostatic chuck electrode disposed on the placing means, and the electrostatic chuck electrode is a dipolar electrostatic chuck electrode divided concentrically into two parts. Further, the object can be realized by the above-mentioned plasma processing apparatus in which high frequencies from the probe high frequency oscillation means are supplied via an antenna disposed within the vacuum reactor, or high frequencies from the probe high frequency oscillation means are supplied via the placing means disposed within the vacuum reactor.

Moreover, the above-mentioned object can be realized by a plasma processing method comprising a step for carrying an object to be processed and placing the same on a placing means within the vacuum reactor, a step for introducing plasma forming gas into the vacuum reactor, a step for controlling the pressure of the gas within the vacuum reactor, a step for generating plasma, a plasma processing step for applying bias to the placing means and subjecting the object to plasma processing, and a step for subjecting the apparatus to plasma cleaning after processing the object using plasma, wherein the method further comprises at least one of a path diagnosis step for supplying high frequencies from a high frequency receiver, a source power supply system or an RF bias system and acquiring the respective reflection characteristics before and after the plasma processing step, or a pre-plasma processing diagnosis step for detecting the plasma impedance or the reflected waves and the transmitted waves, and an apparatus condition determination step for determining the apparatus condition via high frequency analysis based on the variation of a reflection coefficient and a transmission coefficient from an oscillation frequency characteristics before and after the plasma processing step.

Further, the above-mentioned object can be realized by a plasma processing method comprising a step for performing feedback control of an apparatus control parameter during plasma processing so as to control the plasma density and distribution to a constant value based on the result of detecting the impedance of plasma or the reflectance and the transmittance during plasma processing, or a step for changing conditions of the plasma cleaning step. According to the present invention, not only the reflected waves but also the transmitted waves are measured so as to enable detection of not only the density near the reflection receivers but also the change of plasma distribution between the oscillation unit and the receivers.

### BRIEF DESCRIPTION OF THE DRAWINGS

FIG. 1 is a cross-sectional view of a plasma processing apparatus according to a preferred embodiment of the present invention;

FIG. 2 is an equivalent circuit illustrating the drawing of FIG. 1 of the present invention as an electric circuit;

FIG. 3 is a pattern diagram of the variation of receiver current with time when a 400-kHz RF bias is applied;

FIG. 4 is a pattern diagram of the variation of receiver current with time when the plasma gas is varied;

FIG. 5 is a cross-sectional view of a chamber-embedded high frequency receiver disposed within the vacuum reactor;

FIG. 6 is a pattern diagram taken from the upper side of the chamber-mounted receiver, and a cross-sectional view thereof;

FIG. 7 is a cross-sectional view of a plasma processing apparatus having mounted thereon a high frequency transmitter means according to the preferred embodiment of the present invention;

FIG. 8 is an equivalent circuit showing FIG. 7 of the present invention as an electric circuit;

FIG. 9 is a pattern diagram of the result of measuring the reflection coefficient with respect to the radial direction density A1 and the thickness direction density A2;

FIG. 10 is a view showing the change of probe resonant frequency when the ESC thickness is varied;

FIG. 11 is a view showing an embodiment where the high frequency oscillation means is connected to the side of the lower electrode;

FIG. 12 is a view showing the structure where the electrostatic chuck electrode is formed as a dipole electrostatic chuck portion;

FIG. 13 is a configuration diagram showing the state where a path switching circuit is inserted;

FIG. 14 is a pattern diagram of a receiver having a resonant circuit 305 connected thereto;

FIG. 15 is an overall flowchart showing the plasma processing method according to the present invention; and

FIG. 16 is a flowchart showing the plasma density APC of the present invention.

### DETAILED DESCRIPTION OF THE PREFERRED EMBODIMENTS

### Embodiment 1

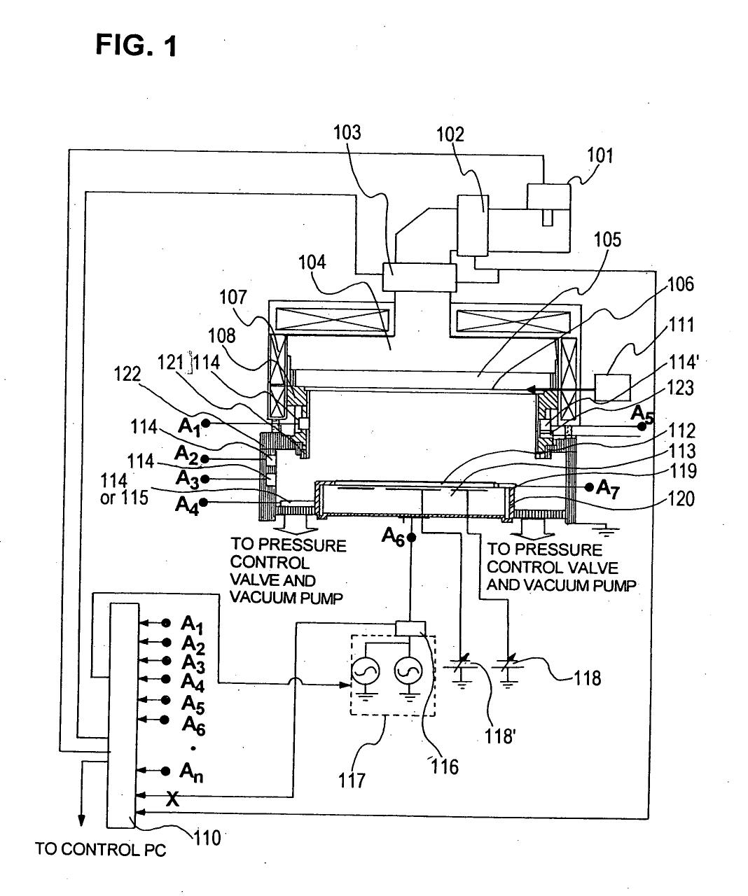

First, an embodiment of an apparatus for realizing the present invention will be described. FIG. 1 is a vertical cross-sectional view showing an outline of the structure of a plasma processing apparatus according to a preferred embodiment of the present invention. The plasma processing apparatus shown in FIG. 1 is a plasma processing apparatus for generating plasma within a plasma processing chamber arranged in the interior of a vacuum reactor, and for processing a substrate-like sample such as a semiconductor wafer as object to be etched disposed within the plasma processing chamber using the generated plasma.

The vacuum reactor of the plasma processing apparatus comprises an etching chamber 108 as plasma processing chamber, a quartz plate 105, a shower plate 106, a gas supply means 111, a base frame 122, a vacuum pump and a pressure control valve (both of which are not shown in FIG. 1).

Means for generating plasma includes a source power supply 101 for generating microwaves of 2.450 GHz, a source electromagnetic wave matching box 102, a cavity resonator 104, and an electromagnet 107. Etching gas is supplied by mixing etching gases via a gas supply means 111 composed of a mass flow controller and a stop valve, and then introducing the mixed etching gas through the shower plate 106 into the etching chamber 108.

A lower electrode 113 for placing an Si (silicon) wafer 112 being the object to be etched comprises on an upper surface thereof a ring-shaped susceptor 120 disposed to cover an outer circumference and a side wall of the placing surface on which the Si wafer 112 is to be loaded, and the temperature of the lower electrode can be stabilized to a given temperature using a temperature control means or the like (not shown in FIG. 1). During the etching process, mutually opposite DC voltages of −2000 through +2000 V generated via two DC power supplies 118 and 118′ are applied to hold the wafer 112 via electrostatic chuck, and pressure control is performed by filling He having superior heat transfer efficiency between the Si wafer 112 and the lower electrode 113. The temperature of the Si wafer 112 during etching can be controlled through such electrostatic chucking technology.

The lower electrode 113 has an RF bias power supply mechanism 117 and an RF bias matching box 116 connected thereto for drawing ions in the plasma toward the wafer 112 and controlling the ion energy distribution thereof. The RF bias power supply mechanism 117 is not composed of a single power supply, but is composed of two power supplies having different frequencies. The bias power of the RF bias power supply mechanism 117 is used to control the energy of incident ions and the distribution thereof. According to the RF bias power supply mechanism 117, when the object to be processed is silicon, silicon nitride, TiN, resist, antireflection film or the like, a minimum power output of approximately 1 W to a maximum power output of approximately 500 W (continuous sine waves) is supplied with respect to the object to be processed having an 12-inch diameter, and a maximum power output of approximately 7 kW is supplied for etching insulating films.

Further, in order to achieve the effect of reducing charge-up damage (electron shading), a mechanism having a time modulating (hereinafter also referred to as TM) function for performing an on-off modulation within the range of 100 Hz through 3 kHz is adopted. By utilizing such RF bias power supply mechanism 117 having dual-frequency power supplies, the ion energy and the ion energy distribution can be changed to correspond to the processing conditions, and the selectivity with respect to the base layer, the expansion of control margin of etching profile, and the controllability of the wafer in-plane distribution of the etching rate can be improved.

The present invention provides to the prior art plasma processing apparatus a means for detecting the plasma distribution, the plasma in-plane density and the consumption level of components. According to the present invention, the above-mentioned means is realized by a high frequency analysis means 110 and receivers disposed within the vacuum reactor (such as a chamber-embedded high frequency receiver 114 or a susceptor-mounting high frequency receiver 119). Therefore, in FIG. 1, the probe high frequency oscillating means are the respective power supplies of the RF bias power supply mechanism 117 or the source power supply 101 being disposed in the apparatus.

At first, during plasma processing, the RF bias power supply mechanism 117 or the source power supply 101 supplies the desired set power either continuously or intermittently into the etching chamber 108. Based on the information on the signal intensity of transmitted waves, the phase thereof, and the harmonic waves received at respective positions via the plurality of high frequency receivers disposed within the etching chamber (chamber-embedded high frequency receivers 114 (points A₁ through A₃ and A₅), a probe high frequency receiver 115 (A₄) disposed within the chamber 108 and a susceptor-mounting high frequency receiver 119 (A₇)), a high frequency analysis means 110 analyzes the plasma density, the change of distribution of plasma density and the component conditions.

At this time, the rotationally symmetric plasma with respect to axis z under a magnetic-field-applied environment existing between the lower electrode and the receivers can be regarded as an electric element having a tensor permittivity represented by the following expression (1). For example, the frequency characteristics of the plasma permittivity ∈ₚ can be expressed by the following expression (1).

$$\begin{matrix}[ Expression 1 ] & \\ {ɛ}_{p} ( ω ) = {ɛ}_{0} ( \begin{matrix}{κ}_{v} & - {jκ}_{d} & 0 \\ {jκ}_{d} & {κ}_{v} & 0 \\ 0 & 0 & {κ}_{h}\end{matrix} ) & ( 1 )\end{matrix}$$

Here, κᵥ, κₕ and κ_{d} denote permittivity components which are a perpendicular component, a parallel component and a diagonal component with respect to the magnetic field expressed by the following expressions (2) through (4). The letter j represents an imaginary unit.

$$\begin{matrix}[ Expression 2 ] & \\ {κ}_{v} ( ω ) = 1 - \frac{ω - j {v}_{m}}{ω} \frac{{ω}_{pe}^{2}}{{( ω - j {v}_{m} )}^{2} - {ω}_{ce}^{2}} & ( 2 ) \\ [ Expression 3 ] & \\ {κ}_{d} ( ω ) = \frac{{ω}_{ce}}{ω} \frac{{ω}_{pe}^{2}}{{( ω - j {v}_{m} )}^{2} - {ω}_{ce}^{2}} & ( 3 ) \\ [ Expression 4 ] & \\ {κ}_{h} ( ω ) = 1 - \frac{{ϖ}_{pe}^{2}}{ω ( ω - j {v}_{m} )} & ( 4 )\end{matrix}$$

Here, ωₚₑ represents the electron plasma frequency represented by the following expression (5), ω_{ce} represents the electron cyclotron frequency represented by the following expression (6), and νₘ, refers to the electrons-neutral collision frequency determined by the pressure and the cross-sections of the gas molecules and atoms.

$$\begin{matrix}[ Expression 5 ] & \\ {ϖ}_{pe}^{2} = \frac{{n}_{e} {q}^{2}}{{m}_{e} {ɛ}_{0}} & ( 5 ) \\ [ Expression 6 ] & \\ {ϖ}_{ce} = \frac{qB}{m} & ( 6 )\end{matrix}$$

In expressions (5) and (6), q represents the elementary charge, mₑ represents the electron mass, ∈ₒ represents the vacuum permittivity and B represents the magnetic field intensity in the direction of axis z.

When high frequency (f=ω/2π) is applied from the lower electrode 112 to a plasma having an electron density nₑ with a tensor permittivity, the high frequency waves E·exp (ik·r−jωt) propagated through the plasma is propagated in the manner shown in expression (7) based on the Maxwell-Boltzmann electromagnetic equation.

$$\begin{matrix}[ Expression 7 ] & \\ \vec{k} \times \vec{k} \times \vec{E} + \frac{{ω}^{2}}{{c}^{2}} \vec{ɛ} \cdot \vec{E} = 0 & ( 7 )\end{matrix}$$

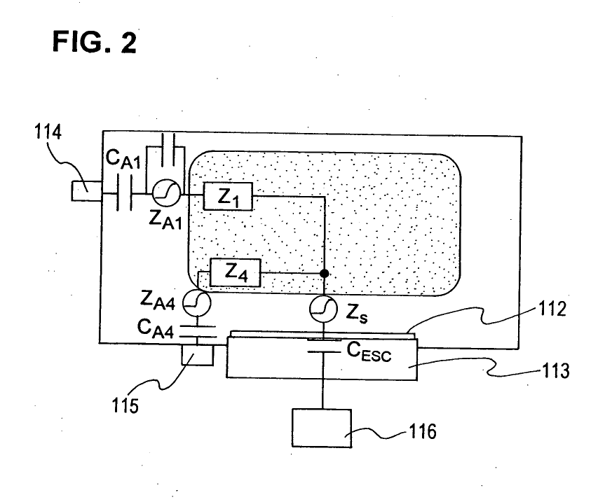

Here, k represents the wave number vector, r represents the position vector, and t represents time. The equivalent circuit within the vacuum reactor at this time is shown in FIG. 2. C_{A1} represents an electrostatic capacitance of the surface insulating film of the wall-surface receiver, and C_{ESC} represents an electrostatic capacitance of the electrostatic chuck film on the surface of the lower electrode 113. Further, Z₁ and Z₄ represent the complex impedance of plasma calculated based on electric field intensity and current of the electromagnetic wave computed as a function of position and time based on expressions (1) through (7) including information on the density and distribution of plasma at the respective mid-flow paths. Zₛ and Z_{A1} represent impedance at the nonlinear portion of the sheath composed of a displacement current and a conduction current via electrons and ions. The plasma sheath is a space in which no charged particles exist, which is formed at a boundary between the plasma and the boundary surface in contact therewith brought about by the difference in the mobility of ions and electrons, and the thickness of the sheath is determined mainly by the plasma density and the electron temperature. Therefore, in an equivalent-circuit point of view, it can be expressed by a capacitor representing the path of displacement current and the conducting current portion composed of electrons and ions showing a nonlinear characteristic. (For simplification, capacitors provided in parallel to Z_{A4} and Z₀ in FIG. 2 are not shown.)

At this time, the current Iᵥ₁ detected by the receiver 114 can be represented by the following expression (8) as impedance Zᵥ₁=(jωC_{ESC})⁻¹+Z₀+Z₁(ω)Z_{A1}(ω)+(jωC_{A1})⁻¹ on the path of the electric circuit.

$$\begin{matrix}[ Expression 8 ] & \\ I = \frac{V}{{Z}_{A 1}} {S}_{k} & ( 8 )\end{matrix}$$

Sₖ is the ratio of the area of the receivers with respect to the total area through which current flows. Therefore, by examining the amount of variation of the current waveform at receiver 114 when the RF bias and the source power supply output have a constant voltage (V=constant) or a constant power (P=VI=constant), it becomes possible to detect the variation of the plasma, the sheath, the coating thickness of components or the like constituting the path. The current value Iₕ₄ with respect to the receiver 115 can also be defined similarly using Z₄.

FIG. 1 illustrates an embodiment of a plasma processing apparatus for detecting the amount of variation of current of the RF bias current applied from the RF bias supply line of the lower electrode 113 into the plasma via a plurality of receivers disposed horizontally and perpendicularly with respect to the surface being processed. In this case, by connecting the signals from the receiver A₄ and the receiver A₇ to the high frequency analysis means 110, the plasma density variation in the direction horizontal to the wafer plane can be detected. Further, by connecting the signals from points A₁, A₂, A₃ and A₅ connected to the receiver 114 to the high frequency analysis means 110, the plasma average density and the change of distribution condition in the height direction (perpendicular direction) can be detected. Moreover, by connecting the point X on the path of the RF bias application mechanism to the high frequency analysis means 110, the plasma density on the plane to be processed and the variation of the electrostatic chuck layer on the lower electrode of the sheath can be detected.

The change in the plasma density distribution using the measurement configuration described above can be detected by extracting and detecting the relative variation of signals B from the plasma radial direction density receivers A4 and A7, the RF bias matching box 116 or the plasma impedance monitor (not shown in FIG. 1) via the high frequency analysis means 110.

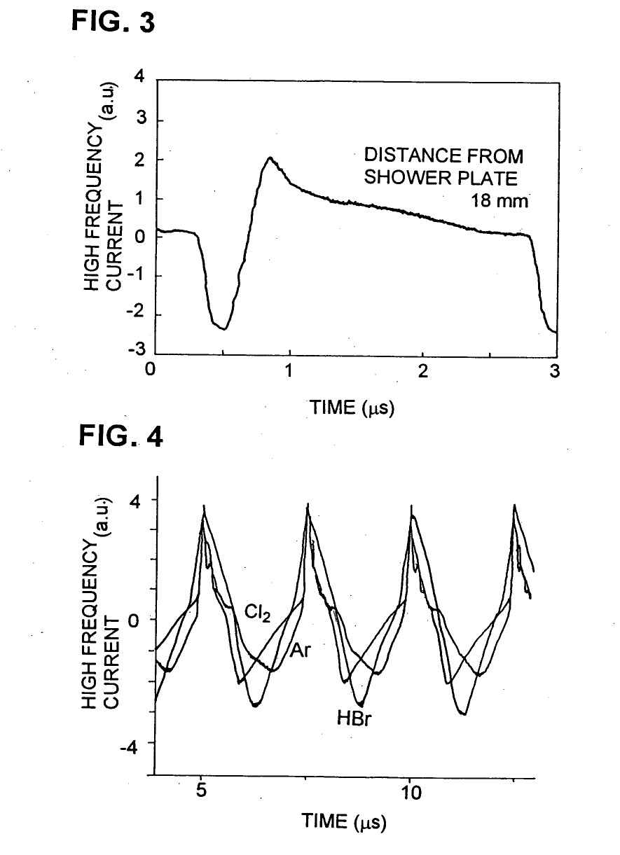

FIG. 3 is a pattern diagram of a current waveform detected by the receiver 114 under the processing conditions of 100 ccm Cl₂ gas, 2 Pa, 500 W source power, and 20 W RF bias. The detected waveform of the high frequency current of 400 kHz supplied from the lower electrode 112 into the plasma is distorted by the nonlinear property of the voltage-current characteristic of the plasma sheath formed near the receiver 114 and the wafer 112 existing in the middle of the current path. Further, the state of the bulk of plasma also existing in the middle of the path is detected as an electromagnetic intensity determined via the propagation expression shown in expressions (1) through (7). Further, as shown in FIG. 4, when the gas species is changed under the processing conditions of 1 Pa pressure, 500 W source power and 10 W RF bias, the difference in ion mass can be detected as the difference in distortion of the current waveform caused by the difference of mobility near the sheath (that is, as the mixture ratio of harmonic waves). In other words, the change of ion species can also be detected by detecting the change in the pattern of harmonic components.

As shown in FIG. 1, by acquiring the difference of current values monitored via multiple adjacent receivers, it becomes possible to eliminate the common portion of the resonator ((jωC_{ESC})⁻¹+Z₀). At this time, the difference of current intensity at the bulk portion (Zₙ(ω)−Zₙ₋₁(ω)) is reflected in the fundamental wave component of the oscillation frequency, and the difference in the variation caused by the sheath portion and the surface insulating layer (Z_{AN}(ω)−Z_{AN-1}(ω))+((jωC_{AN})⁻¹−(jωC_{AN-1})⁻¹) is reflected in the harmonic component caused by the sheath nonlinearity. Therefore, by subjecting the difference of current variation of the adjacent location to fast Fourier transformation, and by performing frequency analysis thereof, it becomes possible to isolate the density variation of the bulk portion from the density variation near the sheath.

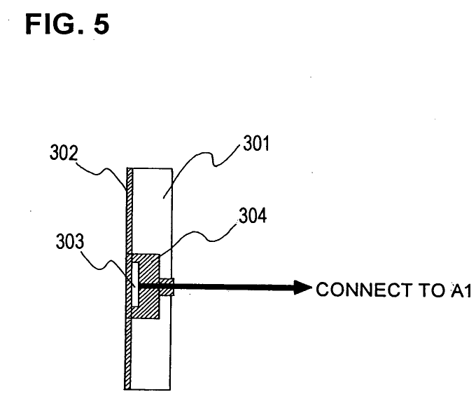

In order to perform such measurement during plasma processing, it is preferable that the respective receivers are positioned at such locations so, as not to affect the etching performance (profile, rate, contamination and deterioration with time), and that they are disposed after thorough consideration of the structure of the plasma processing apparatus. FIG. 5 illustrates an embodiment of the structure of a chamber-embedded high frequency receiver 114. A receiver metal 303 constituting the high frequency receiver is covered by an insulating body 304 from the surrounding wall surface material 301, and insulated from the etching chamber 108. Further, an insulating layer 302 is also attached to the inner circumference side of the etching chamber 108, that is, the surface coming into contact with plasma, in order to prevent metal contamination and generation of particles.

Therefore, it is preferable to attach the same material forming the inner wall of the chamber 108 as the insulating layer 302 on the surface of the receiver. By using the same material forming the surrounding areas of the receiver as the insulating layer, it becomes possible to detect the thickness and the level of damage of the insulating coating on the inner wall of the chamber near the receiver, and thus, it becomes possible to predict the timing for replacing consumable components (such as the earth component 121, the susceptor 119 and the insulating cover), to suppress the deterioration of yield due to particles and contamination, and to reduce the non-operation time of the apparatus for specifying the damaged components. Moreover, the receiver portion must be arranged so that it is flat and has no height difference with the inner wall of the chamber, so as not to cause concentration of plasma generating power and RF bias electric field.

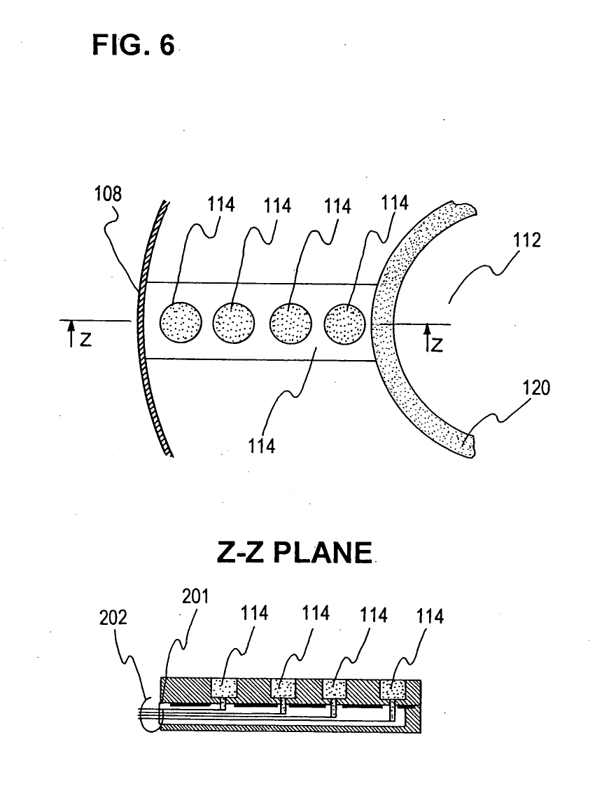

FIG. 6 is a pattern diagram of the chamber-mounted receiver of point A₄. A plurality of cylindrical sensor portions 114 with a diameter of approximately 1 cm and having the cross-sectional structure illustrated in FIG. 5 are arranged with an interval of approximately 1 cm. The shape can either be cylindrical or square, but the receive sensitivity is enhanced as the area increases. Therefore, in consideration of the tradeoff with the positional analyzing ability, the shape and area thereof should be determined to suit the apparatus. As described, by measuring the change of plasma density distribution in the radial direction at plural locations in the non-wafer-processing area, it becomes possible to detect the change of plasma density near the side wall of the chamber and or the susceptor with greater spatial resolution. Such multi-structure signal portion is adopted not only in chamber-mounted receivers but also in chamber-embedded receivers. The chamber-mounted receiver is independent, can be arranged at any optional position, and is effective during development of apparatuses or processes, while the chamber-embedded receiver is preferably applied to mass-production apparatuses since it does not require coaxial cables as signal lines which may cause contamination and plasma disturbance.

By adopting the present invention, it becomes possible to extract and isolate from the radical distribution contribution portion the varying component of the plasma density distribution that is the cause of the results such as the in-plane distribution of gate critical dimension (CD) of a patterned wafer or the in-plane distribution of etching rate, the result being relied upon for developing processes according to the prior art method.

According to the present invention, an accurate profile control and distribution control corresponding to the cause of changes thereof can be performed. For example, when the peak to peak voltage in the matching box 116 or the plasma density detected via A₇ and A₄ and converted is deteriorated from the center of the moving radius toward the outer circumference thereof, the plasma density distribution control mechanism 103 or the output power of the source power supply 101 can be controlled so as to increase the plasma density at the end of the apparatus. In contrast, if the density detected via the Vₚₚ of the matching box 116 or the density detected via points A₇ and A₄ is not varied but the CD or the like is varied greatly, it is determined that the radical species distribution has changed, and the temperature distribution on the wafer is changed via the rate of in-plane distribution of gas supply or the lower electrode temperature control means (not shown in FIG. 1), according to which the temperature distribution on the wafer is varied and the in-plane distribution of the radical absorption probability is controlled.

Similarly, by using the signals from the density receivers (points A₁ through A₃) in the perpendicular direction in addition to the sensor unit in the horizontal direction with the surface of the object to be processed to perform APC control in a similar manner, it becomes possible to suppress the change of etching performance (change of process profile) caused by the varied chamber wall status. Such APC function can be controlled by directly controlling the mechanism for suppressing distribution and fluctuation (such as the plasma density distribution control mechanism 103 or the gas supply in-plane distribution ratio control mechanism) via the high frequency analysis means 110, or can be controlled through a PC for controlling the apparatus.

Furthermore, by adding the high frequency analysis means for detecting and controlling the variation of plasma density and distribution according to the present invention to a prior art monitor signal (such as plasma emission spectroscopy, peak to peak voltage (Vₚₚ) of RF bias, gas pressure and matching box parameters, or the impedance measured via a commercially-available plasma impedance monitor independently connected near an RF bias matching box), it becomes possible to isolate the respective ion flux, the radical composition, the ion energy and the changes of distributions thereof, according to which an APC control for making the physical quantity for controlling the etching profile constant becomes possible. For example, in order to set the density change to fall within an allowable value according to the present invention under constant pressure, constant gas flow rate and constant composition, the plasma source power or the distribution control mechanism 103 can be controlled to first make the plasma density and distribution constant, and then to make the Vₚₚ or the RF bias power constant. Such APC control enables the ion flux and energy to be controlled directly and to suppress the etch rate variation and CD variation caused by charged particles.

In the embodiment of FIG. 1, two power supplies outputting two different frequencies are provided as the RF bias power supply mechanism. The frequencies should preferably combine a plurality of bias frequencies composed of a relatively low frequency band (100 k through 2 MHz) sensitive to the nonlinearity of the sheath and the variation of plasma potential, and a relatively high frequency band (2 M through 13.56 MHz) capable of transmitting through a thin sheath, easily propagated through the plasma and sensitive to the earth structure of the chamber, but contributes very little to generating plasma (for example, a combination of 400 kHz and 13.56 MHz or 4 MHz). By applying these various frequencies to plasma processing and detecting the changes in the fundamental waves and the harmonics, it becomes possible to improve the detection accuracy of the three-dimensional plasma special distribution within the chamber including the space above the electrode, the density variation thereof and the consumption of components of the transmitter and receiver.

### Embodiment 2

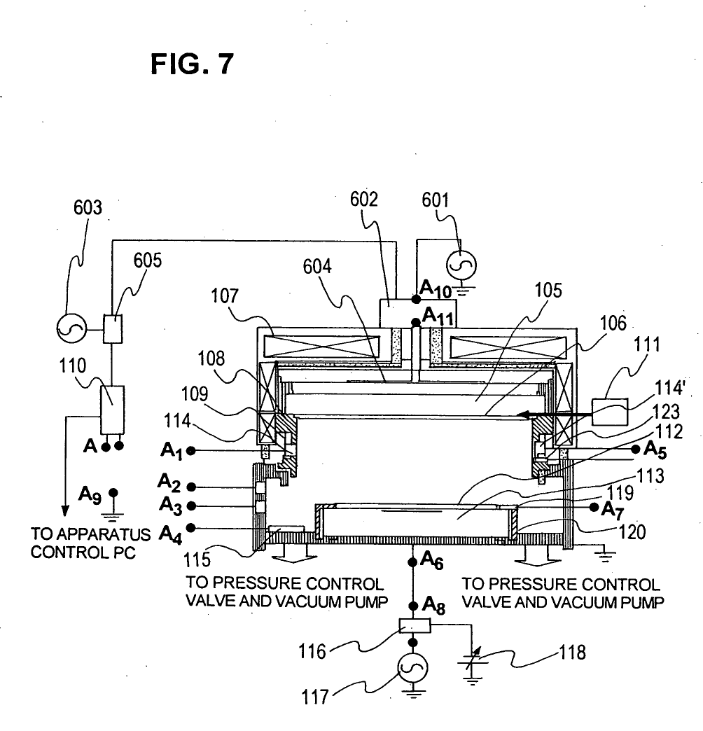

In addition to the example described above where the frequency of the RF bias power supply connected to the lower electrode is utilized as a high frequency oscillator, a method for detecting the conditions of the plasma and the apparatus by connecting a third probe power supply will now be described. FIG. 7 shows an embodiment having means for irradiating UHF waves from the surface of a UHF matching box 602 constituting a plasma generating power supply system through an antenna 604 into the plasma chamber, and connecting at least one of the plurality of connecting points A₁ through A₉ to point A, thereby measuring the reflection coefficient, the transmission coefficient and the impedance.

Embodiment 2 differs from embodiment 1 illustrated in FIG. 1 in that the present embodiment comprises a 450-MHz UHF power supply 601 as plasma source power supply constituting a plasma generating means, a UHF matching box 602 and an antenna 604. The antenna 604 for irradiating UHF waves into the etching chamber 108 constituting the vacuum reactor is disposed on an atmospheric side from the quartz plate 105 for maintaining vacuum.

Embodiment 2 provides to a conventional plasma processing apparatus a means for detecting the plasma in-plane density and distribution and the level of consumption of the components. Further, embodiment 2 differs from embodiment 1 in that a probe high frequency oscillating means 603 as third probe power supply is connected to the apparatus.

The probe high frequency oscillation means 603 has a function to output sine waves of approximately 1 W or smaller so as not to affect plasma generation or plasma processing, and to temporally sweep the probe frequency (approximately 100 kHz to 3 GHz). In substitution thereof, it is also possible to narrow down the functions and to oscillate a plurality of characteristic frequencies continuously or intermittently. Furthermore, the probe high frequency can be oscillated through the antenna 604 into the etching chamber 108, or oscillated through a probe high frequency receiver 115 as oscillator disposed within the chamber 108.

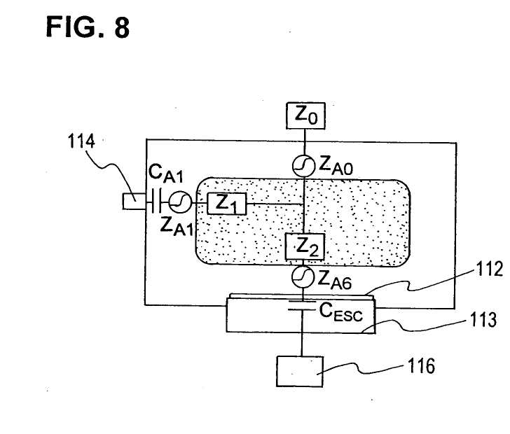

An equivalent circuit within a vacuum reactor when high frequency (f=ω/2π) is supplied into the vacuum reactor via an antenna 604 with respect to a plasma having an electron density nₑ as according to the apparatus of embodiment 2 will be illustrated in FIG. 8. In FIG. 8, Zₒ denotes the characteristic impedance of the oscillation portion. A reflection coefficient r (reflected wave intensity/incident wave intensity) detected by connecting to a chamber-embedded high frequency receiver 114 (for example, point A₁ of FIG. 7) can be expressed by the following expression (9) as impedance of the path of the electric circuit Zᵥ₁=Z₁(ω)+Z_{A1}(ω)+Z_{A0}(ω)+(jωC_{A1})⁻¹. Z₀ denotes the characteristic impedance of the circuit.

$$\begin{matrix}[ Expression 9 ] & \\ Γ = \vert \frac{{Z}_{0} - {Z}_{v 1}}{{Z}_{0} + {Z}_{v 1}} \vert & ( 9 )\end{matrix}$$

The impedance Zₕ corresponding to the plasma in the horizontal direction with respect to the processing surface of the object can be defined similarly using Z_{A6}. At this time, since the resonant frequency illustrated in the following expression (1) absorbs the oscillation high frequency based on the inductor component L and the capacitor component C of the imaginary portion of Zₕ, the reflection coefficient is reduced by the frequency of expression (5) corresponding to plasma density, the resonant frequency of the components of the apparatus or the frequencies of the harmonics thereof.

$$\begin{matrix}[ Expression 10 ] & \\ ω = \frac{1}{\sqrt{LC}} & ( 10 )\end{matrix}$$

On the other hand, regarding transmittance (transmitted wave intensity/incident wave intensity), since absorption occurs near the plasma oscillation frequency corresponding to the plasma density existing on the path, the transmittance is reduced when observed. Based on the above principle, by examining the time variation of the frequency of the reflection absorption peak or the transmission peak, it becomes possible to detect the variation of the average density of plasma existing in the path between the oscillation device and the receiver, and the consumption of the components in the apparatus. The plasma density or the consumption of components based on the resonant frequency is computed via the high frequency analysis means 110 or the control PC.

In FIG. 7, points A₁, A₂, A₃ and A₅ are points for measuring the impedance of the path including the average density intersecting the radial direction of plasma (corresponding to the path including Z₁ of FIG. 8), and points A₄, A₆, A₇ and A₈ are points for measuring the impedance of the path including the density in the thickness direction of plasma. Of the points for measuring the thickness-direction density, point A₆ includes information on the impedance of the lower electrode 113 (impedance of the electrostatic chuck film and wafer) other than the plasma density information, and point A₈ further includes information on the impedance of the RF bias matching box 116.

Other than on the locations for disposing receivers (114, 115, 119) from point A₁ to point A₉, it is also possible to dispose point A to fall on ground A₁₀ of the apparatus, but in that case, the paths of the electric circuit of the oscillation frequency are summed, so that it becomes difficult to specify components or to specify plasma distribution, but since it enables to monitor the conditions of all the paths at once, it is effective as a rough variation detection. Further, in the high frequency analysis means 110, by measuring the change of frequency ratio between point A₁ and A₃ which are radial direction receivers perpendicular to the probe high frequency oscillation surface and the thickness direction receiver (point A₄ or point A₆) on a plane parallel to the probe high frequency oscillation surface, it is possible to detect the general change of plasma density distribution. As described, the high frequency analysis means 110 must have a means for measuring two or more ports simultaneously.

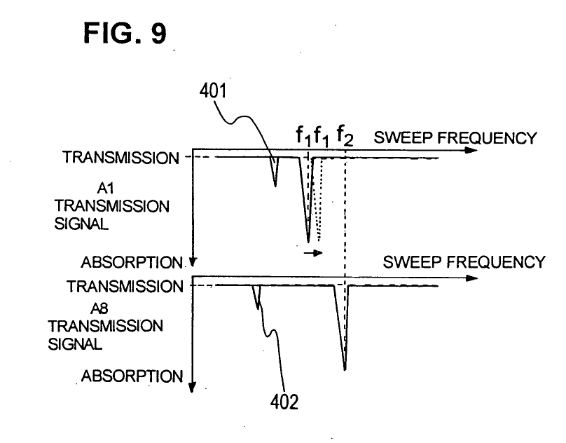

FIG. 9 is a pattern diagram showing the result of measuring the transmission coefficient via the radial direction density A₁ received via the receiver A₁ and the thickness direction density received via the receiver A₈. The plasma processing method for managing the plasma density distribution and the apparatus condition will be described with reference to the drawing. Initially during plasma processing, peaks appeared at f₁ of the reflection coefficient of point A₁ and at f₂ of point A₈, but as the number of wafers subjected to plasma processing increases, the detection peak of point A₁ was shifted to point f′₁. Such change indicates that the plasma density in the radial direction partially increased (the density at the end portion increased) due for example to the change of wall surface condition.

Therefore, an APC control corresponding to the true cause of change of the processing profile can be performed by controlling the apparatus control parameter for controlling distribution (such as the coil current), and not by changing the apparatus control parameter for reducing the plasma density (such as the UHF power). At this time, the change of the condition of components can be detected by recognizing which component was resonated by the resonance peak obtained simultaneously via frequency sweep, and by examining the variation of the resonance peak 401.

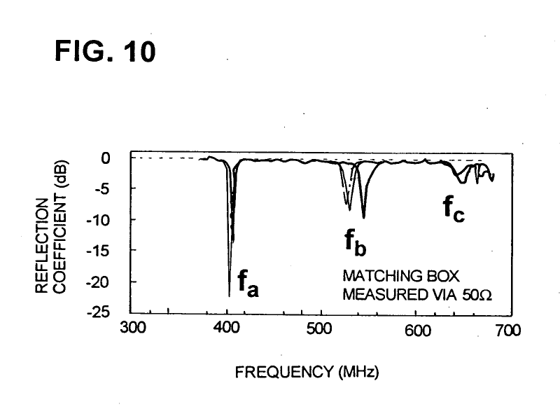

FIG. 10 shows the result of measuring the reflected wave intensity by connecting a probe high frequency oscillation means and a high frequency analysis means to A₁₀ as shown in FIG. 7 during chamber idling, and measuring the intensity when the ESC is new (solid line) and when the ESC layer is reduced by 100 μm (dotted line). Absorption peaks are observed at positions fₐ, f_{b} and f_{c} of the frequency-swept probe high frequency. Of the peaks, f_{b} is changed in response to the change of ESC layer thickness, and the amount of change is 76 kHz with respect to the layer reduced by 100 μm. In other words, it shows that the amount of change of the peak frequency of f_{b} can be diagnosed with superior sensitivity without releasing the chamber to atmosphere, the change being 0.05% with respect to a distance of approximately 200 mm between the lower electrode 113 and the antenna 604. As described, by monitoring the amount of temporal change of the resonance peak corresponding to a component disposed on the measurement path, it becomes possible to predict the degree of consumption of the component and the timing of replacement thereof. By arbitrarily selecting the location of connection of the probe high frequency means and the high frequency analysis means, it becomes possible to detect the respective degree of consumption of the quartz parts or the susceptor via a similar method.

Further, during the inspection for shipping the apparatus, by inspecting the level of plasma density and distribution via the same probe high frequency oscillation means 603 and the high frequency analysis means 110, and based on the result, constituting a conversion table of the apparatus control parameters so as to match the plasma density and distribution determined as shipping standard, and creating a table for each apparatus, it becomes possible to compensate for the inter-apparatus or inter-chamber differences regarding plasma density and distribution. Furthermore, by performing the measurement of the present invention after replacing components during maintenance of the apparatus, it becomes possible to manage with high accuracy the electrical and mechanical assemblies of the components constituting the source-power system and the RF bias supply system related to the plasma density and distribution and the assembly level of the earth or the like on the chamber side wall, by which the reproducibility after assembly can be improved.

In order to actualize the plasma processing method for detecting the plasma distribution and managing the apparatus conditions, it is necessary to superpose the probe high frequency oscillation means 603 to the power supply system of the plasma generation means. Therefore, the probe high frequency oscillation means 603 must have high withstand voltage and directionality with respect to the frequency and output of the plasma generating power supply (for example, the UHF power supply 601). This can be actualized for example by inserting a directional coupler, a filter and an attenuator for large power to the power supply system within the UHF matching box 602 (for example, by connecting to A₇ of FIG. 6) or outside the UHF matching box 602 (for example, by connecting to A₅). The oscillation frequency at that time should preferably use a frequency range including the frequency range corresponding to the plasma density shown in expression (5) (for example, a frequency of 284 to 875 MHz when the Ar plasma density nₑ equals 10¹⁵ through 10¹⁶ cm⁻³).

On the other hand, with respect to the high frequency analysis means 110, the receiver A₆ and the receiver A₈ disposed on the RF bias supply side may be connected to A of the high frequency analysis means 110, so that it must have withstand voltage with respect to the RF bias power or the leaked plasma frequency power. The receiver A₈ and the receiver A₉ should preferably be disposed within the RF bias matching box 116 so that the wiring can be orderly arranged and excessive noise or the like can be prevented from entering. Further, in order to acquire a frequency dependency of the reflection coefficient as shown in FIG. 9, the high frequency analysis means 110 has a function to vary the receive band in synchronism corresponding to the sweep timing of the frequency oscillated from the probe high frequency oscillation means 603.

As described, by providing an oscillator that differs from the power supply frequencies of the plasma generating means and the RF bias power supply mechanism, it becomes possible to detect the plasma density and distribution and the plasma impedance even under plasma conditions where RF bias is not output (for example, in a trimming process for reducing the resist mask dimension or in an in-situ cleaning process having no object placed on the lower electrode). Furthermore, by combining the present invention and the prior art monitor values (such as plasma emission spectroscopy, peak to peak voltage of RE bias, gas pressure and matching box parameters), it becomes possible to isolate and respectively control the plasma density, the plasma distribution thereof and the variation of neutral radicals according to embodiment 1. Since the components of the apparatus can be managed using the oscillation peaks unique to the components, management of the components, prevention maintenance and factorial analysis of the apparatus are facilitated, and the most appropriate correction and maintenance can be performed based on the causes.

### Embodiment 3

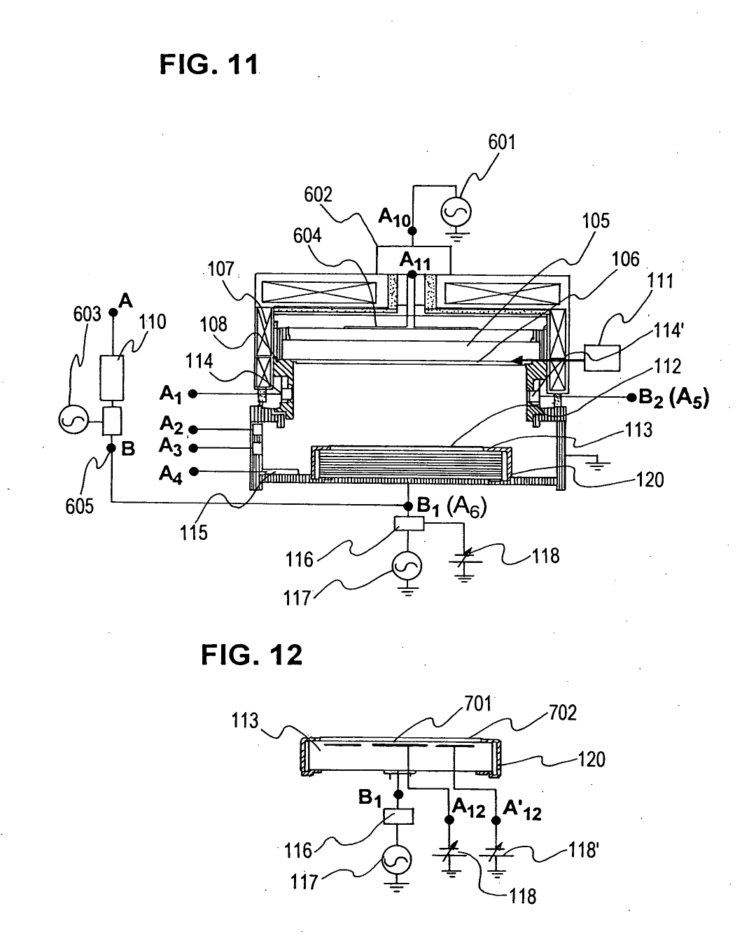

FIG. 11 is referred to in illustrating another embodiment where the forms of connection of the probe high frequency oscillation means and the high frequency analysis means differ from FIG. 7. The plasma processing apparatus according to the present embodiment differs from the plasma processing apparatus illustrated in FIG. 7 in that the probe high frequency oscillation means 603 is connected via a directional coupler 605 to a connecting point B₁ (A₆ in FIG. 7) of the RF bias matching box 116 and the lower electrode 113.

In other words, the present embodiment is an example where the probe high frequency oscillation means 603 is connected to an RF power supply line of the lower electrode 113. In this example, the thickness direction density can be detected by connecting the signals from receiver A₁₀ and receiver A₁₁ to the high frequency analysis means 110. Further, the average density of plasma intersecting the radial direction of the chamber and the change in the distribution condition thereof can be detected by disposing a probe high frequency oscillation unit 114′ at a rotational symmetric position of point A₁, connecting point B₂ with end B, and connecting point A₁ connected to the receiver 114 with end A.

### Embodiment 4

An embodiment of a method for performing electrostatic chuck of the wafer on a lower electrode 113 via a dipole system will be described with reference to FIG. 12 illustrating the structure of the lower electrode 113. In the present embodiment, the electrostatic chuck electrode disposed within the lower electrode 113 is divided into two concentric parts, an inner-side electrostatic chuck electrode 701 and an outer-side electrostatic chuck electrode 702, wherein for example, as shown in FIG. 7, probe high frequency waves are oscillated from the probe high frequency oscillation means 603 via a directional coupler 605 through an antenna 604 (plasma source side), and receive points A₁₂ and A₁₂′ between two DC power supplies 118 and 118′ for applying voltages that differ from the respective electrostatic chuck electrodes 701 and 702 illustrated in FIG. 12 are respectively connected to end A of the high frequency analysis means 110. As described, in the case of a dipole-type electrostatic chuck, the electrostatic chuck electrodes 701 and 702 disposed within the lower electrode 113 can be utilized as the high frequency receiver portions, and the in-plane distribution above the object to be processed can be detected according to the number of division of the dipole electrode.

Further according to FIG. 12, when the probe high frequency oscillation means 603 is connected via the directional coupler 605 to the side of the electrostatic chuck electrodes 118 or 118′ of point A₁₂ or point A₁₂′ to supply the probe high frequency to the chamber 108, the electrostatic chuck electrodes 701 and 702 can be commonly used as the probe high frequency oscillation electrodes. The present embodiment is effective in cases where the plasma source adopts a microwave waveguide for example in which transmission paths having cut-off frequencies exist in a mixture, according to which points A₁₀ and A₁₁ cannot be used.

As described, as shown in FIG. 11 or FIG. 12, by oscillating the probe high frequency from the lower electrode side, and connecting the signals received via the receivers A₁ through A₅ to the high frequency analysis means 110, it becomes possible to detect the change of radial direction density distribution in the manner illustrated in embodiment 2. Further, in order to detect the change of plasma density distribution in the radial direction, a plurality of pairs of transmitters and receivers disposed to intersect the plasma corresponding to A₁ and A₅ (B₂) should be provided, and the information thereof should be averaged so as to reduce errors.

As described in embodiments 1 through 4, the mechanisms for oscillating the probe high frequency into the plasma (in the case of embodiment 1, the existing power supply such as the RF bias power supply is commonly used for oscillating probe high frequency) and for receiving the probe high frequency from the plasma (such as the chamber-embedded high frequency receivers 114 and 115, the electrostatic chuck electrodes 701 and 702, and the antenna 604 shown in FIGS. 1, 7, 11 and 12) should be connected so that plasma exists therebetween, and the receiver means and the transmitter means can have identical structures as shown in FIG. 5, so that they do not have to be distinguished. Therefore, it is preferable that the positions of the transmitters and receivers connected to the high frequency analysis means 110 are arbitrarily determined to positions where the reflection coefficient sensitivity of the component to be examined is greatest. For example, if the level of particle attachment, deposition and chipping of the plasma processing chamber wall surface must be detected, point A₁ connected to the chamber-embedded high frequency receiver 114 and point B₂ connected to the chamber-embedded high frequency receiver 114′ should be connected to end B.

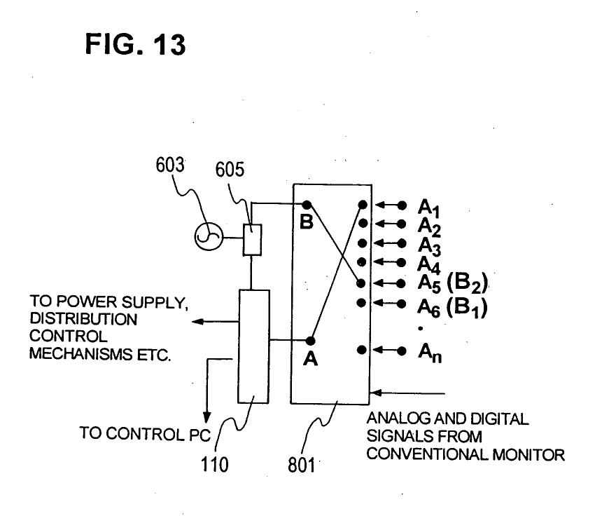

By providing a path switching circuit as shown in FIG. 13, it becomes possible to select any arbitrary path of the plurality of transmitters and receivers with respect to one pair of high frequency oscillation means and high frequency analysis means, regardless of the transmitters and receivers.

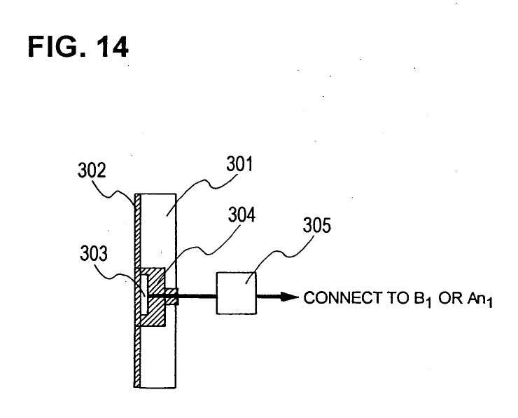

Further, as shown in FIG. 14, by connecting the chamber embedded/mounted high frequency receivers 114 and 115 to the probe high frequency oscillation means and forming a resonant circuit 305 by combining capacitors and coils so that it resonates with a capacitor capacity formed by the insulating layer 302 within the oscillation frequency range (from 100 kHz to 3 GHz), it becomes possible to detect the variation of the apparatus to be measured even though it does not resonate intrinsically. For example, the end point of wall surface cleaning can be determined by setting a certain point of time of the chamber as reference and by detecting the variation of shift quantity of the created reflection absorption frequency during in-situ cleaning, according to which the frequency peak corresponding to the electrostatic capacity variation in response to the reaction products deposited on the surface is varied. At the same time, according to the present embodiment, even in locations where plasma does not exist, the deposition film can be detected by adjusting the resonant frequency, so that the amount of particles caused by deposits within the chamber can be predicted and preventive maintenance for suppressing the deterioration of yield caused by particles can be performed.

According further to the method for introducing probe high frequency toward the lower electrode 113, since the method is sensitive to the change of density immediately above the wafer, the method can be used to determine the end point of etching together with the change of plasma density and distribution through detection of the time variation of the reflection coefficient during the etching process.

As for apparatuses using other plasma sources such as the inductively coupled plasma (ICP) or the capacitively coupled plasma (CCP), the portion related to the antenna 604 of FIG. 7 differs according to the change in the plasma source and excitation frequency, but basically, by connecting the probe high frequency oscillation means from the plasma source power supply side as shown in FIG. 7 and by disposing a plurality of receivers as shown in FIG. 7, the plasma processing method for detecting the plasma density, plasma distribution and the apparatus condition according to the present invention can be actualized. Instead, it is also possible to oscillate the probe high frequency from the lower electrode side on which the object to be processed is placed, as shown in FIG. 9.

### Embodiment 5

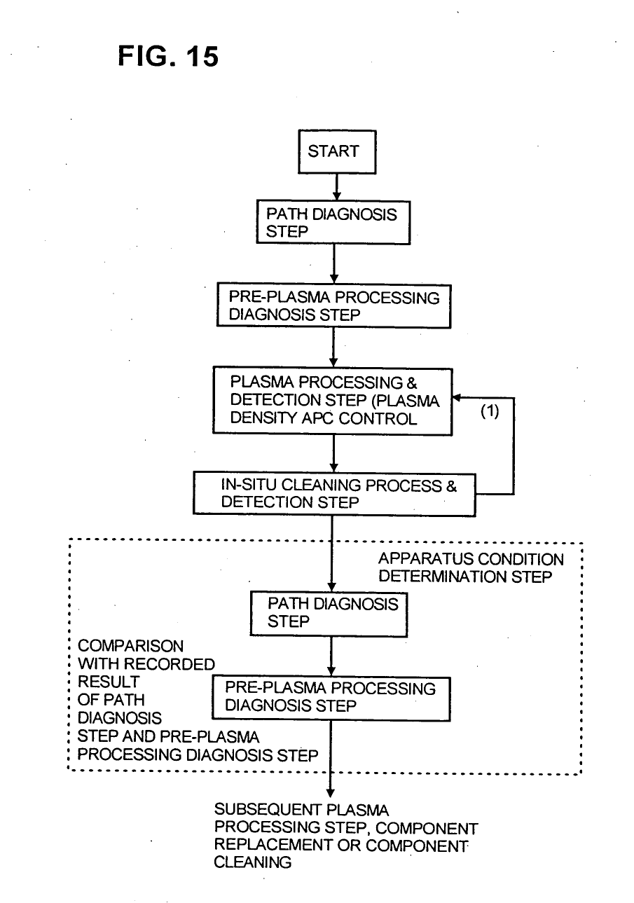

A plasma processing method illustrated in FIG. 15 using the plasma processing apparatus according to the present invention will now be described. The plasma processing method according to the present embodiment comprises a step for carrying an object to be processed into the vacuum reactor of the plasma processing apparatus and placing the same on a stage means, a step for introducing gas into the vacuum reactor, a step for controlling the pressure within the vacuum reactor, a step for generating plasma within the vacuum reactor by applying plasma generating high frequency voltage, a step for applying a bias voltage to the stage means, and a step for subjecting the apparatus to plasma cleaning after processing the object via plasma, wherein the method further comprises a path diagnosis step and a pre-plasma processing diagnosis step prior to the plasma processing step, a density detecting step (plasma density APC control step) and a plasma-density-detected in-situ cleaning step, and an apparatus condition determination step composed of the aforementioned path diagnosis step and the pre-plasma processing diagnosis step after the plasma and in-Situ cleaning processing.

According to the path diagnosis step, when the apparatus is started or the cleaning of components thereof is completed, for example, the high frequency oscillation means is connected to the high frequency transmitters and receivers, the source power supply system or the RF bias system, so as to acquire the respective reflection characteristics thereof. According to this step, the plurality of receivers can be corrected prior to plasma processing, and the initial conditions of the source power supply system and the RF supply system can be recognized. In the case of FIG. 1, since there is no high frequency oscillation unit 603, it is possible to use a network analyzer instead of the high frequency oscillation unit 603 and the high frequency analysis apparatus 110.

In the pre-plasma processing diagnosis step, the high frequency oscillation means or the high frequency receivers are connected as shown in FIG. 1, 7 or 11, so as to detect the plasma impedance, the reflected waves and the transmitted waves during discharge of inert gas or cleaning gas in a waferless state, and to recognize the electrical initial state under reference plasma.

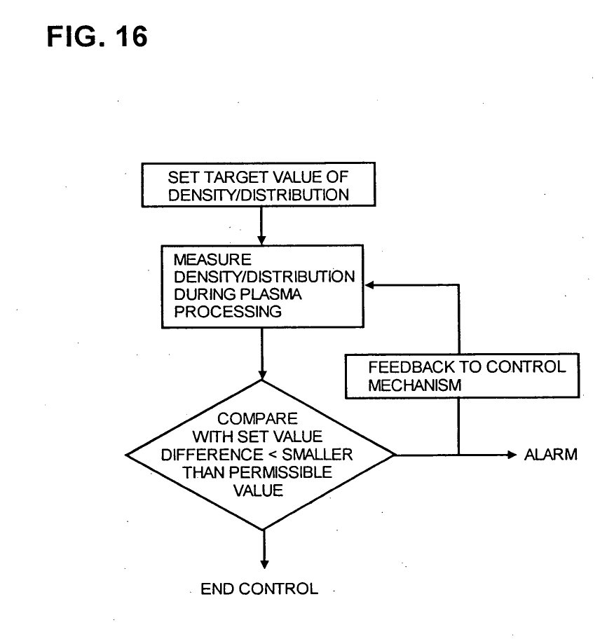

A step of detecting the plasma density and plasma distribution during plasma processing and of controlling the same to a constant value (plasma density control APC step) will now be illustrated in FIG. 16. The method is composed of a step of setting the plasma density and plasma distribution in advance, a step of applying probe high frequency from a probe high frequency oscillation means into the vacuum chamber during plasma processing of an object in an apparatus having the high frequency oscillation means and the high frequency receiver connected thereto as shown in FIGS. 1, 7 and 11, and measuring the change of impedance of the path and the bulk plasma density and distribution via a high frequency analysis means, and either a step of performing feedback control of the apparatus control parameter during plasma processing based on the difference from the set target value or the result of comparison from the aforementioned apparatus condition or a step of outputting an alarm for warning. Thus, it becomes possible to make the physical quantities such as the plasma density and distribution contributing directly to the etching profile constant, and to realize a stable processing performance.

In an in-situ cleaning process and detecting step, it is possible to detect and determine the end point of removal of the attached particles near the receiver that cannot be detected via plasma emission corresponding to the receiver position via a step for detecting the change of impedance or the reflected waves and transmitted waves based on the signals from the high frequency oscillation means and the high frequency receiver as shown in FIGS. 7 and 11 during in-situ cleaning performed after every processing. At that time, the sensitivity correction of the receivers and the determination of consumption level of the components of the apparatus can be performed by performing continuous processing when the change of apparatus condition is within a permissible value, or by re-inserting the aforementioned pre-plasma processing diagnosis step and the path diagnosis step when the change of apparatus condition exceeds the permissible value, and subsequent plasma processing, component replacement or cleaning can be performed in response to the detected level.

Based on the above method, it becomes possible to determine the change of condition of the receivers, the change of plasma density and distribution, the level of consumption of the components and the level of cleaning, so as to realize stabilized processing profile via diagnosis of apparatus condition and APC control using plasma density.

What is claimed is:

1. A plasma processing apparatus comprising a vacuum reactor, a gas supplying means for introducing plasma-forming gas into the vacuum reactor, a pressure control means for controlling the pressure of said gas introduced into the vacuum reactor, a plasma generating means for generating plasma using the gas introduced into the vacuum reactor, a placing means for placing an object to be subject to plasma processing in the vacuum reactor, and a high frequency bias applying means for applying high frequency bias to the placing means,
wherein the apparatus further comprises:
a probe high frequency oscillation means for supplying into the vacuum reactor a minute output oscillation frequency that differs from a plasma source power supply of the plasma generation means and from a high frequency bias power supply of the high frequency bias applying means;
a plurality of high frequency transmitter and receiver means disposed along a parallel direction and a perpendicular direction with respect to the surface of the object to be processed for receiving the high frequency supplied from the probe high frequency oscillation means via a plane that contacts the plasma via an insulating layer; and
a high frequency analysis means for measuring the impedance per oscillation frequency or for measuring a reflectance and a transmittance per oscillation frequency within an electric circuit formed of the probe high frequency oscillation means and the high frequency transmitter and receiver means, and computing a variation of the density and distribution of the plasma using the measured impedance or the measured reflectance and transmittance.

2. The plasma processing apparatus according to claim 1, wherein
the probe high frequency oscillation means is the high frequency bias power supply or the plasma source power supply having a plurality of varied frequencies.

3. The plasma processing apparatus according to claim 1, wherein
the probe high frequency oscillation means has a frequency sweeping means, wherein the sweep oscillation frequency supplied by the frequency sweeping means contains a plasma frequency corresponding to the plasma density, and the high frequency transmitter and receiver means synchronizes with the sweeping oscillation frequency.

4. The plasma processing apparatus according to claim 3, wherein
a range of the sweeping oscillation frequency supplied by the probe high frequency oscillation means is 100 kHz or greater and 3 GHz or smaller.

5. The plasma processing apparatus according to any one of claims 1 through 4, wherein
the high frequency transmitter and receiver means disposed along the horizontal direction with respect to the surface of the object to be processed is an electrostatic chuck electrode disposed on the placing means.

6. The plasma processing apparatus according to claim 5, wherein
the electrostatic chuck electrode is a dipolar electrostatic chuck electrode divided concentrically into two parts.

7. The plasma processing apparatus according to claim 5, wherein
high frequencies from the probe high frequency oscillation means are supplied via an antenna disposed within the vacuum reactor.

8. The plasma processing apparatus according to claim 1, wherein
high, frequencies from the probe high frequency oscillation means are supplied via the placing means disposed within the vacuum reactor.

9. A plasma processing method comprising a step for carrying an object to be processed and placing the same on a placing means within the vacuum reactor, a step for introducing plasma-forming gas into the vacuum reactor, a step for controlling the pressure of the gas within the vacuum reactor, a step for generating plasma, a plasma processing step for applying bias to the placing means and subjecting the object to plasma processing, and a step for subjecting the apparatus to plasma cleaning after processing the object using plasma, wherein
the method further comprises at least one of a path diagnosis step for supplying high frequencies from a high frequency receiver, a source power supply system or an RF bias system and acquiring the respective reflection characteristics before and after the plasma processing step, or a pre-plasma processing diagnosis step for detecting the plasma impedance or the reflected waves and the transmitted waves; and
an apparatus condition determination step for determining the apparatus condition via high frequency analysis based on the variation of a reflection coefficient and a transmission coefficient from an oscillation frequency characteristics before and after the plasma processing step.

10. The plasma processing method according to claim 9, wherein
the plasma processing step comprises a step for detecting the plasma density and distribution and controlling the same to a constant value.

11. The plasma processing method according to claim 9, further comprising
a step for changing conditions of the cleaning step in response to the variation of the plasma density and distribution detected via the plasma processing step.

12. The plasma processing method according to claim 11, wherein
the cleaning step comprises a step for detecting an end point of the cleaning based on the changes of impedance of the receiver portion and the reflectance.
